(19) United States
(12) Patent Application Publication
(10) Pub. No.: US 2025/0299903 A1
(43) Pub. Date: Sep. 25, 2025

(54) Aberration Correction Device and Aberration Correction Method

(71) Applicant: Hitachi High-Tech Corporation, Minato-ku, Tokyo (JP)

(72) Inventors: Michiko SUZUKI, Tokyo (JP); Yudai KUBO, Tokyo (JP)

(21) Appl. No.: 18/869,511

(22) PCT Filed: Jun. 27, 2022
(86) PCT No.: PCT/JP2022/025576

§ 371 Date: Nov. 26, 2024

(51) Int. Cl. H01J 37/14; H01J 37/147; H01J 37/28

(52) U.S. Cl. CPC H01J 37/14; H01J 37/1472; H01J 37/28; H01J 2237/152; H01J 2237/1532; H01J 2237/1534; H01J 2237/2802

(57) ABSTRACT

An aberration correction device that corrects an aberration of an optical system includes: a first multi-pole lens configured to generate a first 6-pole field; a second multi-pole lens configured to generate a second 6-pole field; a first deflector configured to generate a first deflection field; and a second deflector configured to generate a second deflection field. The first deflector is arranged at a position of a beam cross between the first multi-pole lens and the second multi-pole lens, and the second deflector is arranged between the first deflector and the first multi-pole lens or the second multi-pole lens. The aberration correction device returns, by the second deflector, a beam deflected by the first deflector, allows the beam to pass through at least one center of the first multi-pole lens or the second multi-pole lens, and accordingly, corrects at least one of a 2-fold symmetric first-order astigmatism (A1) aberration or a 5-fold symmetric fourth-order astigmatism (A4) aberration.

### TECHNICAL FIELD

The present invention relates to an aberration correction device and an aberration correction method, and for example, relates to a scanning transmission electron microscope including the aberration correction device.

### BACKGROUND ART

In a scanning electron microscope (SEM) or a scanning transmission electron microscopy (STEM), the smaller a diameter of an electron beam (probe) for scanning a sample, the higher a resolution capability. The diameter of the probe is mainly limited by a third-order spherical surface (C3) aberration of an objective lens, but in recent years, an apparatus on which an aberration corrector for correcting the aberration is mounted is put into practical use.

As the aberration corrector, there is known an aberration corrector provided with two multi-pole lenses for generating a 6-pole field and two axially symmetric lenses arranged therebetween. For example, PTL 1 discloses that “two circular lenses having the same focal length are arranged between a first sector pole and a second sector pole at an interval twice as long as the focal length and further at an interval corresponding to the focal length of the circular lens from a plane passing through a center of the sector pole adjacent to each circular lens”.

As described above, the C3 aberration can be corrected by the aberration corrector, but in the practical use, an aberration referred to as a parasitic aberration is generated due to imperfection of the aberration corrector, in other words, a positional deviation of individual poles constituting the multi-pole lens, a variation in magnetic characteristics of pole materials, an axial deviation of each lens, and the like.

The generated third or lower order parasitic aberrations are a 2-fold symmetric first-order astigmatism (A1) aberration, a 1-fold symmetric second-order coma (B2) aberration, a 3-fold symmetric second-order astigmatism (A2) aberration, a 2-fold symmetric third-order star (S3) aberration, and a 4-fold symmetric third-order astigmatism (A3) aberration.

As the parasitic aberration, there is a fourth or higher order aberration, and when the higher order aberration is corrected, an aberration free angle range (flat area) is enlarged. Accordingly, it is possible to achieve both a high probe current and a high spatial resolution capability. The fourth-order parasitic aberration includes a 5-fold symmetric fourth-order astigmatism (A4) aberration, a 1-fold symmetric fourth-order coma (B4) aberration, a 3-fold symmetric fourth-order three-lobe (D4) aberration, and the like.

In relation to a method for correcting the S3 aberration and the A3 aberration which are the third-order main parasitic aberration, PTL 2 discloses a method for independently correcting the two-fold symmetric third-order star aberration (S3) and the four-fold symmetric third-order astigmatism aberration (A3) which are generated secondarily by providing a spherical surface aberration corrector. PTL 2 discloses “a charged particle beam apparatus including a spherical surface aberration correction device in which a transmission lens is arranged between a first multi-pole lens and a second multi-pole lens, the charged particle beam apparatus including: a first deflection unit configured to deflect a charged particle beam so as to tilt the charged particle beam entering the first multi-pole lens with respect to an optical axis; a second deflection unit configured to deflect the charged particle beam so as to shift the charged particle beam entering the second multi-pole lens with respect to the optical axis; a third deflection unit configured to deflect the charged particle beam so as to return the charged particle beam emitted from the second multi-pole lens onto the optical axis; and a control unit configured to control the first deflection unit, the second deflection unit, and the third deflection unit, wherein the control unit supplies a control signal to the first deflection unit and the second deflection unit, so that a shift amount of the charged particle beam entering the second multi-pole lens with respect to the optical axis changes in conjunction with an inclination angle with respect to the optical axis of the charged particle beam entering the first multi-pole lens so as to correct a 2-fold symmetric third-order star aberration without influencing a 4-fold symmetric third-order astigmatism aberration or correct the 4-fold symmetric third-order astigmatism aberration without influencing the 2-fold symmetric third-order star aberration.

### CITATION LIST

### Patent Literature

PTL 1: JP2002-510431A
PTL 2: JP5743698B

### SUMMARY OF INVENTION

### Technical Problem

However, in the related art, a method for correcting a fourth-order parasitic aberration such as an A4 aberration independently with high accuracy is not established. When the A4 aberration becomes apparent, it is necessary to reassemble the aberration corrector again, which is a cause of a decrease in yield during production.

As the method for correcting the fourth-order or higher order parasitic aberration, there is a method for deflecting a trajectory of an electron beam passing through the multi-pole lens constituting the aberration corrector, but if the higher order aberration is corrected accordingly, a large variation in a third or lower order parasitic aberration (in particular, the A1 aberration) secondarily occurs.

As an A1 aberration correction method currently in practical use, a method for translating an optical axis with respect to a multi-pole lens and a method for superimposing a 4-pole field on a multi-pole lens are exemplified. A problem when a high-order aberration correction is performed by deflecting the trajectory of the electron beam passing through the multi-pole lens described above is that the method cannot be compatible with the A1 correction method for translating the optical axis with respect to the multi-pole lens. This is because when the optical axis is translated with respect to the multi-pole lens to correct the A1 aberration, a correction for a high-order aberration is cancelled.

Therefore, when the trajectory of the electron beam passing through the multi-pole lens is deflected to perform the high-order parasitic aberration, it is required to superimpose the 4-pole field on the multi-pole lens as the method for correcting the A1 aberration. In order to perform the 4-pole field superposition in any direction on the multi-pole lens, a multi-pole lens having 12 or more poles is generally required. This is because it is necessary to superimpose the 4-pole field and the deflection field for canceling the 6-pole field for correcting the C3 aberration and the deflection field that is secondarily generated when the 6-pole field is generated. Further, in order to superimpose the multi-pole fields having any intensities and directions, it is necessary to control each pole independently. Therefore, a power supply equivalent to the number of poles is required, and as the number of power supplies increases, the beam deflection sensitivity due to the noise increases, which causes deterioration of an image resolution capability

The invention is made to solve such a problem, and an object of the invention is to provide an aberration correction device and an aberration correction method capable of correcting the A1 aberration or the A4 aberration and improving image quality by reducing a beam deflection sensitivity of a multi-pole lens.

### Solution to Problem

An example of an aberration correction device according to the invention is an aberration correction device that corrects an aberration of an optical system, the aberration correction device including:
a first multi-pole lens configured to generate a first 6-pole field;
a second multi-pole lens configured to generate a second 6-pole field;
a first deflector configured to generate a first deflection field; and
a second deflector configured to generate a second deflection field, in which
the first deflector is arranged at a position of a beam cross between the first multi-pole lens and the second multi-pole lens,
the second deflector is arranged between the first deflector and the first multi-pole lens or the second multi-pole lens, and
the aberration correction device
   returns, by the second deflector, a beam deflected by the first deflector,
   allows the beam to pass through at least one center of the first multi-pole lens or the second multi-pole lens, and
   accordingly, corrects at least one of a 2-fold symmetric first-order astigmatism (A1) aberration or a 5-fold symmetric fourth-order astigmatism (A4) aberration.

An example of an aberration correction method according to the invention is an aberration correction method performed by a charged particle beam apparatus including an aberration correction device that corrects an aberration of an optical system, the aberration correction device including
a first multi-pole lens configured to generate a first 6-pole field,
a second multi-pole lens configured to generate a second 6-pole field,
a first deflector configured to generate a first deflection field, and
a second deflector configured to generate a second deflection field, in which
the first deflector is arranged at a position of a beam cross between the first multi-pole lens and the second multi-pole lens, and
the second deflector is arranged between the first deflector and the first multi-pole lens or the second multi-pole lens,
the aberration correction method including:
returning, by the second deflector, a beam deflected by the first deflector;
allowing the beam to pass through at least one center of the first multi-pole lens or the second multi-pole lens; and
accordingly, correcting at least one of a 2-fold symmetric first-order astigmatism (A1) aberration or a 5-fold symmetric fourth-order astigmatism (A4) aberration.

### Advantageous Effects of Invention

According to the aberration correction device and the aberration correction method in the invention, it is possible to achieve both corrections of the A1 aberration or the A4 aberration and improvement on image quality by reducing beam deflection sensitivity of a multi-pole lens.

### BRIEF DESCRIPTION OF DRAWINGS

FIG. 1 is a diagram showing an example of a configuration of a scanning transmission electron microscopy to which an aberration correction device according to Embodiment 1 of the invention can be applied.

FIG. 2 is a diagram showing a configuration of the aberration correction device according to Embodiment 1.

FIG. 3 is a diagram showing a 12-pole lens constituting the aberration correction device according to Embodiment 1.

FIG. 4 is a diagram showing excitation directions for constituting a 6-pole field in the aberration correction device according to Embodiment 1.

FIG. 5 is a diagram showing excitation directions for constituting a deflection field in the aberration correction device according to Embodiment 1.

FIG. 6 is a diagram showing an example of a ray diagram when an A1 aberration correction method in the related art is performed using the aberration correction device according to Embodiment 1.

FIG. 7 is a diagram showing a method for correcting an A1 aberration and an A4 aberration by the aberration correction device in FIG. 2.

FIG. 8 is a diagram showing a procedure for correcting the A1 aberration and the A4 aberration by the aberration correction device in FIG. 2.

FIG. 9 is a diagram showing Ronchigram changes after introducing the A1 aberration and after introducing the A4 aberration by the aberration correction device in FIG. 2.

FIG. 10 is a diagram showing a result of an A4 aberration measurement obtained by the aberration correction device in FIG. 2.

FIG. 11 is a graph showing a relationship between an excitation amount of a third multi-pole lens and an A4 aberration coefficient in the aberration correction device in FIG. 2.

### DESCRIPTION OF EMBODIMENTS

Hereinafter, an embodiment of the invention will be described with reference to the drawings. However, the invention is not to be construed as being limited to the description of the following embodiment. It will be easily understood by those skilled in the art that a specific configuration can be changed without departing from the concept or spirit of the invention.

Notations of “first”, “second”, “third”, and the like in the present specification and the like are used to identify the components, and the numbers and the order are not necessarily limited.

In order to facilitate understanding of the invention, a position, a size, an appropriation, a range, and the like of each configuration shown in the drawings and the like may not represent an actual position, size, appropriation, range, and the like. Therefore, the invention is not limited to the position, the size, the shape, the range, and the like disclosed in the drawings and the like.

### Embodiment 1

### <Configuration of Charged Particle Beam Apparatus>

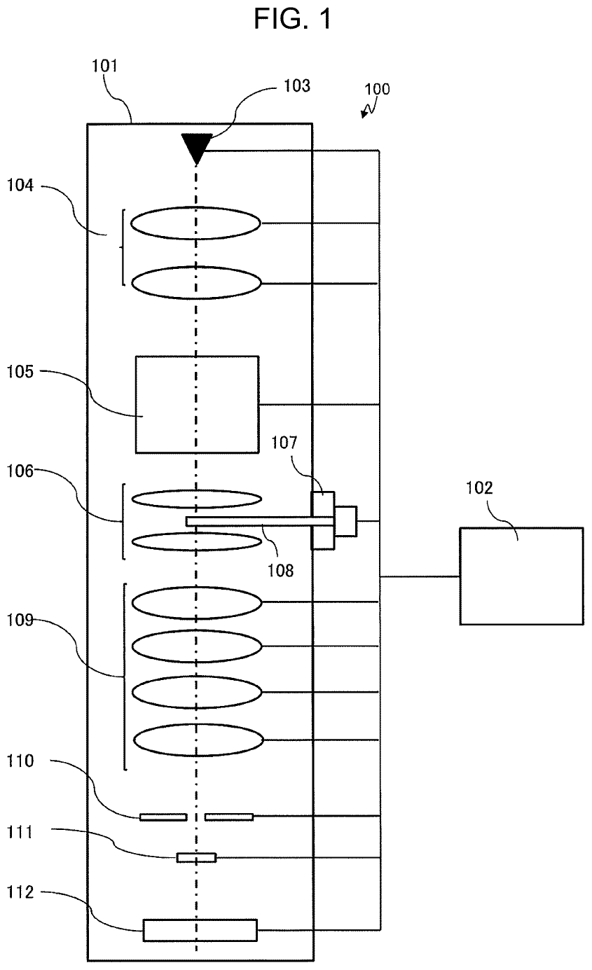

FIG. 1 is a diagram showing an example of a configuration of a charged particle beam apparatus according to Embodiment 1 of the invention. In Embodiment 1, the charged particle beam apparatus is a scanning transmission electron microscopy (STEM) apparatus, and may be another charged particle beam apparatus.

The STEM apparatus 100 includes a lens barrel 101 and a control unit 102. The lens barrel 101 includes an electron source 103 for generating an electron beam, a focusing lens group 104, an aberration correction device 105, an objective lens 106, a sample stage 107, a sample holder 108, an image forming lens group 109, an annular detector 110 for detecting electrons scattered by a sample, a transmission electron detector 111 that detects electrons transmitted through the sample, and an imaging camera 112 for imaging a Ronchigram.

Although not shown, the control unit 102 includes an electron gun control circuit, an irradiation lens control circuit, a condenser diaphragm control circuit, an aberration correction device control circuit, a deflector control circuit, an objective lens control circuit, a camera control circuit, and the like.

The control unit 102 can acquire a value of a target device via a control circuit, and creates any electron optical condition by controlling the target device via the control circuit. The control unit 102 is an example of a control mechanism that implements control of the lens barrel 101.

### <Configuration of Aberration Correction Device>

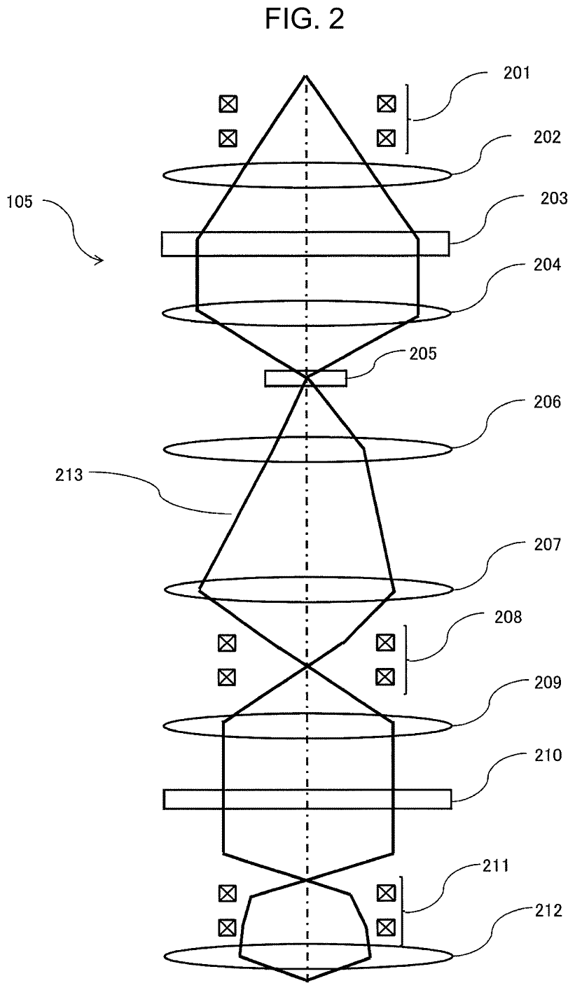

FIG. 2 is a diagram showing an example of a configuration of the aberration correction device 105 according to Embodiment 1. The aberration correction device 105 is a device that corrects an aberration of an optical system. The aberration correction device 105 includes a first deflection coil 201, a first adjustment lens 202, a first multi-pole lens 203, a first transfer lens 204, a third multi-pole lens 205, a second transfer lens 206, a third transfer lens 207, a second deflection coil 208, a fourth transfer lens 209, a second multi-pole lens 210, a third deflection coil 211, and a second adjustment lens 212.

The first multi-pole lens 203 generates a first 6-pole field, and the second multi-pole lens 210 generates a second 6-pole field. The first multi-pole lens 203 and the second multi-pole lens 210 are in a conjugate relationship using the first transfer lens 204, the second transfer lens 206, the third transfer lens 207, and the fourth transfer lens 209. That is, in this configuration, since a main surface of the first multi-pole lens 203 is projected onto the second multi-pole lens 210 at a magnification of 1, it is possible to cancel a second-order astigmatism (A2) aberration and generate a negative third-order spherical surface (C3) aberration by providing a 6-pole field to the first multi-pole lens 203 and providing a 6-pole field having the same intensity but in an opposite phase to the first multi-pole lens 203 to the second multi-pole lens 210.

After a C3 aberration of the objective lens is corrected by the negative C3 aberration generated as described above, a fifth-order astigmatism (A5) aberration remains except for a parasitic aberration. By providing the 6-pole field to the third multi-pole lens 205 arranged at an intermediate position between the first transfer lens 204 and the second transfer lens 206, it is possible to generate the A5 aberration and cancel the remaining A5 aberration. Although the aberrations up to the fifth-order can be corrected in this manner, aberrations referred to as the parasitic aberrations are generated due to a positional deviation of individual poles constituting the multi-pole lens, a variation in magnetic characteristics of pole materials, an axial deviation of each lens, and the like.

The parasitic aberration includes a 2-fold symmetric first-order astigmatism (A1) aberration, a 1-fold symmetric second-order coma (B2) aberration, a 3-fold symmetric second-order astigmatism (A2) aberration, a 2-fold symmetric third-order star (S3) aberration, a 4-fold symmetric third-order astigmatism (A3) aberration, a 5-fold symmetric fourth-order astigmatism (A4) aberration, a 1-fold symmetric fourth-order coma (B4) aberration, a 3-fold symmetric fourth-order three-lobe (D4) aberration, and the like. Correcting the parasitic aberration is important for practical use of the aberration correction device. The configuration of the aberration correction device 105 shown in FIG. 2 is an example and is not limited thereto. At least one transfer optical system (for example, a transfer lens) and at least two multi-poles may be provided.

With respect to an off-axis beam trajectory 213, the beam is tilted by the first transfer lens 204, forms a beam cross by the third multi-pole lens 205, and enters the second transfer lens 206. That is, the third multi-pole lens 205 is arranged at a position of the beam cross between the first multi-pole lens 203 and the second multi-pole lens 210. The number of the positions of the beam cross between the first multi-pole lens 203 and the second multi-pole lens 210 is two in the example in FIG. 2, and is not limited thereto. The number of the positions of the beam cross between the first multi-pole lens 203 and the second multi-pole lens 210 is preferably an even number.

The second deflection coil 208 is arranged between the third multi-pole lens 205 and the second multi-pole lens 210. As a modification, the second deflection coil 208 can be arranged between the third multi-pole lens 205 and the first multi-pole lens 203.

In the present embodiment, the third multi-pole lens 205 functions as a first deflector to generate a first deflection field (note: in the present embodiment, the third multi-pole lens 205 is referred to as the “first deflector” instead of the first deflection coil 201). The second deflection coil 208 functions as a second deflector to generate a second deflection field.

### <Configuration of Multi-Pole Lens>

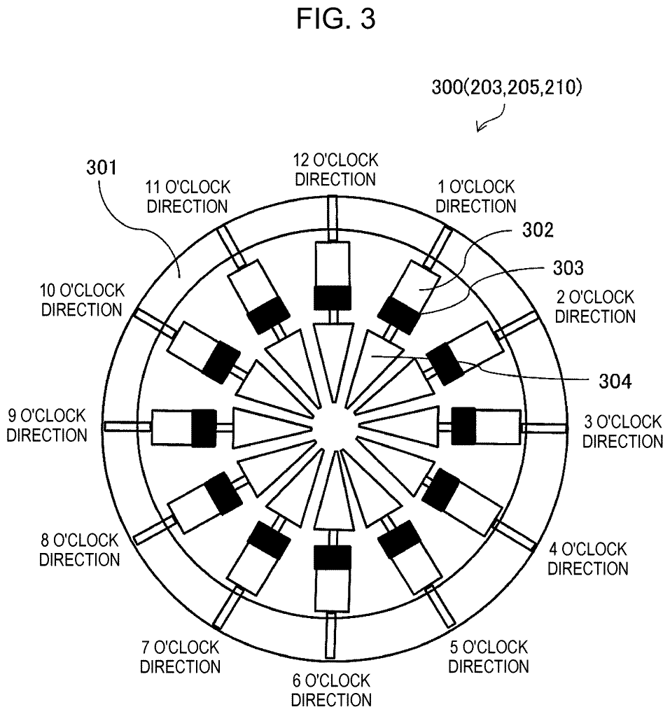

As the multi-pole lens used in the aberration correction device 105, for example, a 12-pole lens is used. FIG. 3 is an example of a structure of the 12-pole lens. By setting the number of poles to twelve, it is possible to add 6-pole fields in two directions, and thus it is possible to generate a 6-pole field of any phase.

In a configuration of a 12-pole lens 300, twelve magnetic poles 304 to which a main coil 302 and a sub coil 303 are attached are arranged along a ring-shaped magnetic path 301. The main coil 302 is a coil for exciting a 6-pole field for generating the negative third-order spherical surface aberration, and the sub coil 303 is a coil for generating each multi-pole field for canceling a deflection field, a 4-pole field, and the like that are secondarily generated when the 6-pole field is generated. In the present embodiment, the 12-pole lens 300 shown in FIG. 3 is used as the first multi-pole lens 203, the second multi-pole lens 210, and the third multi-pole lens 205.

### <Generation of 6-Pole Field>

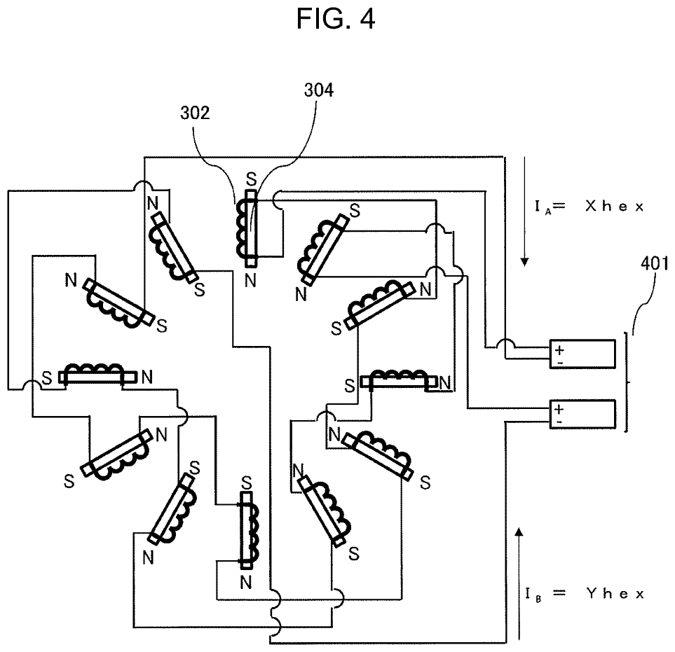

FIG. 4 shows a method for exciting the main coil for generating the 6-pole field. As shown in FIG. 4, every other main coil 302 is connected in series. The main coils 302 directly connected to each other have opposite polarities. By exciting these main coils 302 using a power supply 401, it is possible to generate the 6-pole fields in two directions (X direction and Y direction).

Amounts of currents for exciting the main coils 302 are determined, for example, as follows. Here, I_{A} and I_{B} are each an amount of a current flowing through a respective one of the systems, Xhex corresponds to an intensity of the 6-pole field in the X direction to be generated, and Yhex corresponds to an intensity of the 6-pole field in the Y direction to be generated.

I_{A}=Xhex (Formula 1)

I_{B}=Yhex (Formula 2)

In order to generate the 6-pole field in any direction using the 12-pole lens in this manner, a minimum of two independent power supplies are required. Twelve independent power supplies may be used to independently excite each pole.

### <Generation of Deflection Field>

When deflection fields in two directions (X direction and Y direction) are generated using the twelve sub coils 303, an amount of a current for exciting each sub coil is determined, for example, as follows. Here, In is an amount of a current flowing through the sub coil in an n o'clock direction (1≤n≤12), Xdef corresponds to an intensity of the deflection field in the X direction to be generated, and Ydef corresponds to an intensity of the deflection field in the Y direction to be generated.

When a deflection field in any direction is generated by controlling the amounts of the currents flowing through the twelve sub coils in this manner, twelve independent power supplies are required.

$${I}_{n} = Xdef \times cos ( 2 π \times n / 12 ) + Ydef \times sin ( 2 π \times n / 12 ) \qquad ( Formula 3 )$$

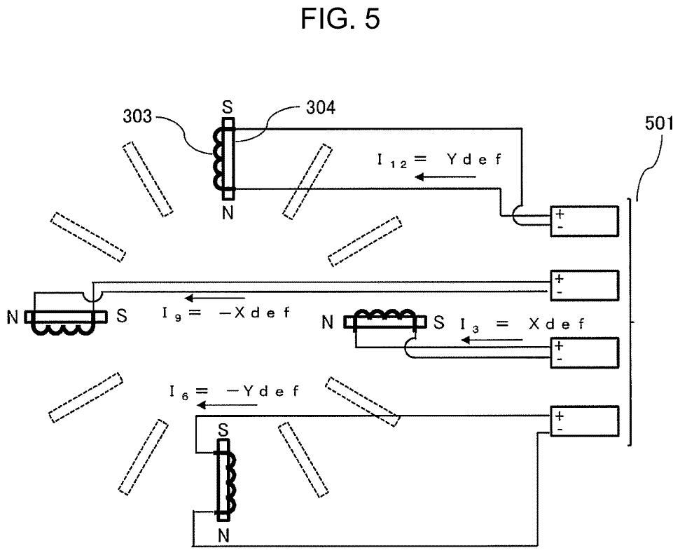

Further, as shown in FIG. 5, deflection fields in two directions (X direction and Y direction) can be generated using four power supplies 501 and two sets of the opposing sub coils 303. For example, four sub coils may be excited as follows.

I₁₂=Ydef (Formula 4)

I₃=Xdef (Formula 5)

I₆=−Ydef (Formula 6)

I₉=−Xdef (Formula 7)

When a deflection field in any direction is generated by controlling the amounts of currents flowing through the four sub coils in this manner, control can be performed by at least two independent power supplies. When the control is performed by the two power supplies, the sub coils in a 12 o'clock direction and a 6 o'clock direction may be connected in series with opposite polarities, and the sub coils in a 3 o'clock direction and a 9 o'clock direction may be connected in series with opposite polarities.

### <Generation of 4-Pole Field>

When 4-pole fields in two directions (X direction and Y direction) are generated using the twelve sub coils 303, an amount of a current for exciting each sub coil 303 is determined, for example, as follows. Here, Iₙ is an amount of a current flowing through the sub coil 303 in the n o'clock direction (n=1 to 12), Xquad corresponds to the intensity of the deflection field in the X direction to be generated, and Yquad corresponds to the intensity of the deflection field in the Y direction to be generated. When the deflection field in any direction is generated by controlling the amounts of the currents flowing through the twelve sub coils 303 in this manner, twelve independent power supplies are required.

$${I}_{n} = Xquad \times cos ( 4 π \times n / 12 ) + Yquad \times sin ( 4 π \times n / 12 ) \qquad ( Formula 8 )$$

### <Superposition of Multi-Pole Field>

When the 6-pole field necessary for the aberration correction is generated by the multi-pole lens, not only the 6-pole field but also the deflection field and the 4-pole field are generated due to the positional deviation of individual poles constituting the multi-pole lens and the variation in magnetic characteristics of pole materials. Therefore, it is common to generate the 6-pole field by the main coils and cancel out unnecessary deflection fields and 4-pole fields by the sub coils.

If the twelve independent power supplies are used for the sub coils as described above, the deflection fields and the 4-pole fields in any directions can be superimposed. However, when the twelve independent power supplies are used, an influence of a noise of the power supplies increases.

When it is assumed that a beam deflection sensitivity on a sample surface by the individual poles of the multi-pole lens is d [pm/μA], a maximum current amount is Iₘ [A], a power supply stability is s [ppm], and the number of poles is N, a total noise d_{N} [pm] is expressed by the following Formula.

$${d}_{N} = 2 \times {I}_{m} \times d \times s \times √ N \qquad ( Formula 9 )$$

Therefore, it is desirable to reduce the number of power supplies used for the sub coils as much as possible.

When there is an unnecessary deflection field, since there is a high risk that the parasitic aberration from a low order to a high order increases due to a tilt of a beam center axis, it is desirable to cancel out the unnecessary deflection field in the multi-pole lens. For the unnecessary 4-pole field, since the beam center axis does not change and only the A1 aberration increases, if a correction unit except for the multi-pole lens can be used, the number of power supplies used for the sub coils can be reduced to at least two.

### <Method for Correcting A1 Aberration and A4 Aberration>

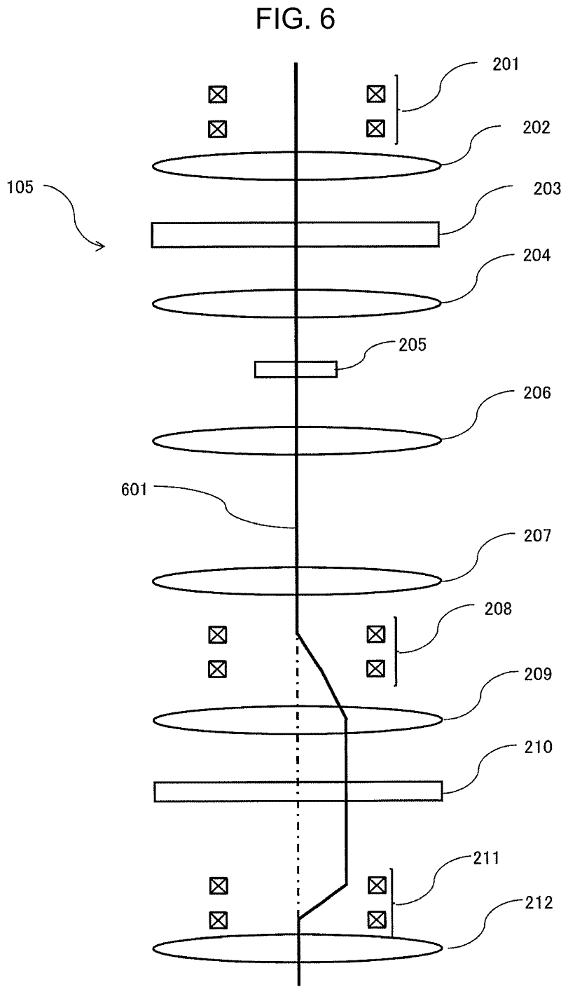

FIG. 6 is a diagram showing an example of a ray diagram when an A1 aberration correction method in the related art that is currently put into practical use is performed using the aberration correction device 105 according to the present embodiment.

The beam has a center trajectory 601. In the aberration correction device 105, an optical axis passes through centers of the individual lenses until the third transfer lens 207. The optical axis is tilted by the second deflection coil 208 and translated with respect to the second multi-pole lens 210. The third deflection coil 211 is adjusted such that the optical axis passes through the center of the second adjustment lens 212.

Under such trajectory control, the A1 aberration is mainly generated, but the third or higher order aberration is slightly generated. Accordingly, a problem of a method for correcting a high-order aberration by deflecting a trajectory of an electron beam passing through the multi-pole lenses described above is that the method cannot be compatible with the A1 correction method shown in FIG. 6. This is because when the optical axis is translated with respect to the multi-pole lens to correct the A1 aberration as shown in FIG. 6, a correction amount of the corrected high-order aberration is cancelled. In this case, the method for correcting the A1 aberration requires 4-pole field superposition on the multi-pole lens, and as the number of power supplies increases as described above, the beam deflection sensitivity due to the noise increases, which causes deterioration of an image resolution capability.

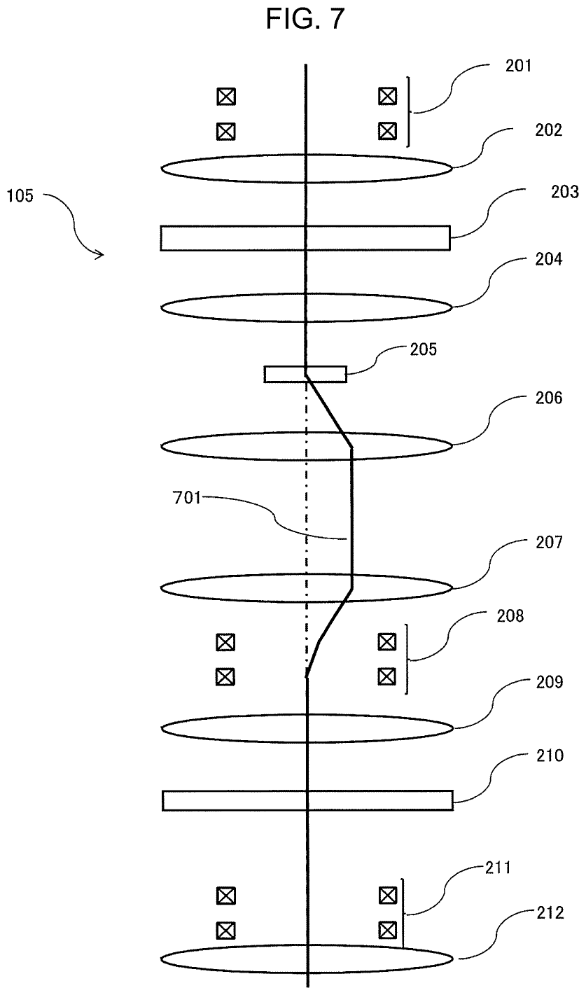

FIG. 7 shows an example of a ray diagram in a method for correcting the A1 aberration and the A4 aberration as an example of the aberration correction method according to the present embodiment. The beam has a center trajectory 701. In the aberration correction device 105 according to the present embodiment, an optical axis passes through the centers of the individual lenses until the first transfer lens 204. The optical axis is tilted by the third multi-pole lens 205 on which the deflection field is superimposed. The second deflection coil 208 is adjusted such that the optical axis passes through the center of the second multi-pole lens 210.

It is possible to control the A1 aberration and the A4 aberration mainly by such trajectory control. This method can be used as the method for correcting the A1 aberration within a range in which the A4 aberration does not cause a problem. That is, the A1 aberration can be corrected. When the A1 aberration is corrected by another method, the A4 aberration can be corrected.

As the method for correcting the A1 aberration, it is possible to correct the A1 aberration using the method of tilting the optical axis by the second deflection coil 208 and translating the optical axis with respect to the second multi-pole lens 210 as shown in FIG. 6, and it is also possible to correct the A1 aberration by the 4-pole field superposition on the multi-pole lens as described above. However, since the number of power supplies increases, it is desirable to correct the A1 aberration by the method shown in FIG. 6.

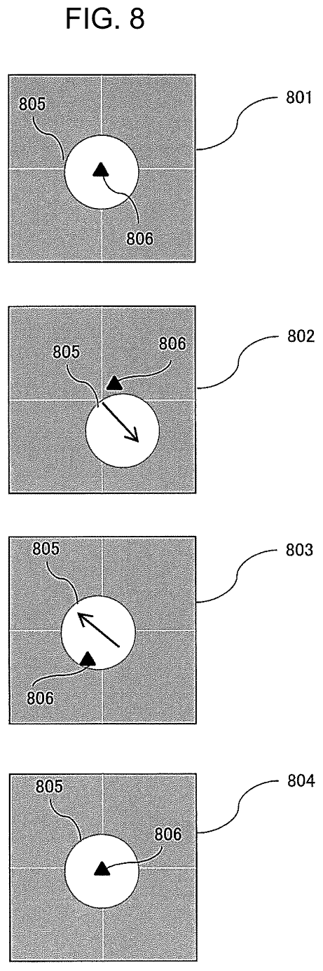

FIG. 8 shows a detailed procedure for performing the trajectory control shown in FIG. 7. In the Ronchigram image, a movement of a field-of-view position with respect to the sample corresponds to a shift movement of the beam, and a movement of a shadow 805 of an aperture of an irradiation system corresponds to a change of a tilt component of the beam.

After a target 806 on the sample and the shadow of the aperture are adjusted to a center of the field-of-view of the camera, when a deflection field is provided to the third multi-pole lens 205, the shadow of the aperture and the target move. A diagram 801 in which the target 806 and the shadow 805 of the aperture are aligned with the center of the field-of-view of the camera and a diagram 802 in which the shadow 805 of the aperture and the target 806 are moved are shown.

The target 806 and the shadow 805 of the aperture thus moved are returned to the center of the field-of-view of the camera using the second deflection coil 208. The second deflection coil 208 is a deflector constituted by upper and lower two stages, and the shift component and the tilt component with respect to the target 806 can be independently controlled by appropriately setting an upper and lower ratio. That is, in the aberration correction device 105 according to the present embodiment, the second deflection coil 208 includes two deflection elements (for example, an upper stage coil and a lower stage coil), and accordingly, the second deflection coil 208 can independently control the deflection and the translation of the beam.

A diagram 803 is shown in which the shadow 805 of the aperture is moved to the center of the field-of-view of the camera. A diagram 804 is shown in which the target 806 is further moved from a state in 803 to the center of the field-of-view of the camera. At this time, by performing control while keeping constant a ratio between a size of the deflection field (for example, the excitation amount of the coil) provided to the third multi-pole lens 205 and the excitation amount during the return by the second deflection coil 208, it is possible to perform the trajectory control of returning to an axis center as shown in FIG. 7 when a deflection field having any size is provided to the third multi-pole lens 205.

As described above, the aberration correction device 105 according to the present embodiment returns, by the second deflection coil 208, the beam deflected by the third multi-pole lens 205 and allows the beam to pass through the center of the second multi-pole lens 210. As a modification, the beam may pass through the center of the first multi-pole lens 203, or the beam may pass through the centers of both the first multi-pole lens 203 and the second multi-pole lens 210.

In this manner, the aberration correction device 105 according to the present embodiment corrects the A4 aberration, and corrects the A1 aberration generated accordingly by
deflecting the beam by the second deflection coil 208 and
translating the optical axis with respect to the 6-pole field generated by the second multi-pole lens 210.

In this manner, both the A1 aberration and the A4 aberration can be corrected.

When both the A1 aberration and the A4 aberration are corrected as in the present embodiment, the aberration can be further reduced in a comprehensive manner. Alternatively, when it is not necessary to correct both the aberrations, only one of the A1 aberration and the A4 aberration may be corrected.

### <Actual Machine Confirmation Result>

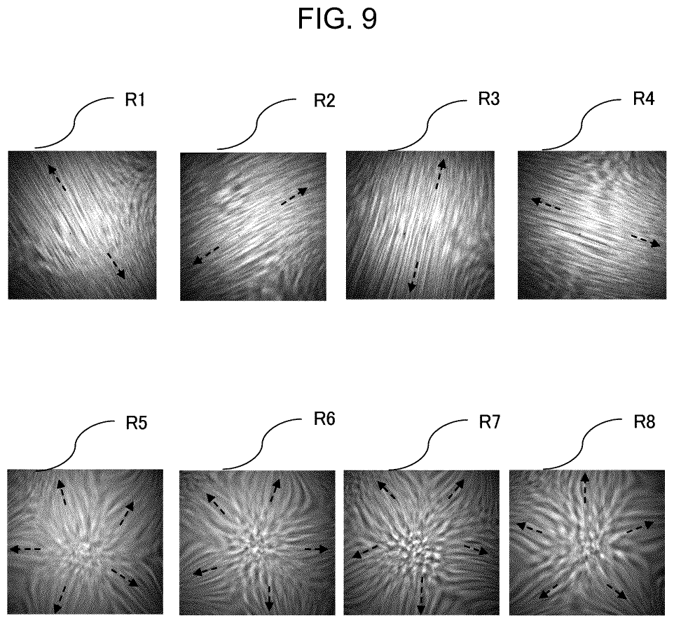

R1 to R4 in FIG. 9 show Ronchigrams in which the A1 aberration is introduced after deflection fields of 0.02 AT in four directions (X+ direction, X− direction, Y+ direction, and Y− direction) are introduced into the third multi-pole lens 205 from a state in which a flat area (aberration free angle range) is sufficiently widened, respectively.

The Ronchigram after introducing the deflection field in the X+ direction is R1, the Ronchigram after introducing the deflection field in the X-direction is R2, the Ronchigram after introducing the deflection field in the Y+ direction is R3, and the Ronchigram after introducing the deflection field in the Y-direction is R4.

Since the A1 aberration appears as a 2-fold symmetric figure on the Ronchigram, 180° corresponds to one period. Accordingly, if rotation control of 180° can be performed on the Ronchigram, the A1 aberrations of all the phases can be generated.

When R1 and R3, R3 and R2, R2 and R4, and R4 and R1 are compared, respectively, it can be seen that R1 and R3, R3 and R2, R2 and R4, and R4 and R1 are rotated by 45 degrees relative to each other. From the above, it was confirmed in an actual machine that when the deflection field provided to the third multi-pole lens 205 is rotated by 90°, a shape of the A1 aberration appearing on the Ronchigram is rotated by 45°.

R5 to R8 in FIG. 9 show Ronchigrams in which deflection fields of 0.3 AT in the four directions (X+ direction, X− direction, Y+ direction, and Y− direction) are introduced into the third multi-pole lens 205 from the state in which the flat area (aberration free angle range) is sufficiently widened, and the A4 aberration remains after the aberration up to the third order is corrected, respectively.

The Ronchigram when introducing the deflection field in the X+ direction is R5, the Ronchigram when introducing the deflection field in the X− direction is R6, the Ronchigram when introducing the deflection field in the Y+ direction is R7, and the Ronchigram when introducing the deflection field in the Y− direction is R8.

Since the A4 aberration appears as a 5-fold symmetric figure on the Ronchigram, 72° corresponds to one period. Accordingly, if rotation control of 72° can be performed on the Ronchigram, the A4 aberrations of all the phases can be generated.

When R5 and R7, R7 and R6, R6 and R8, and R8 and R5 are compared, respectively, it can be seen that R5 and R7, R7 and R6, R6 and R8, and R8 and R5 are rotated by 18 degrees relative to each other. From the above, it was confirmed in the actual machine that when the deflection field provided to the third multi-pole is rotated by 90°, a shape of the A4 aberration appearing on the Ronchigram is rotated by 18°.

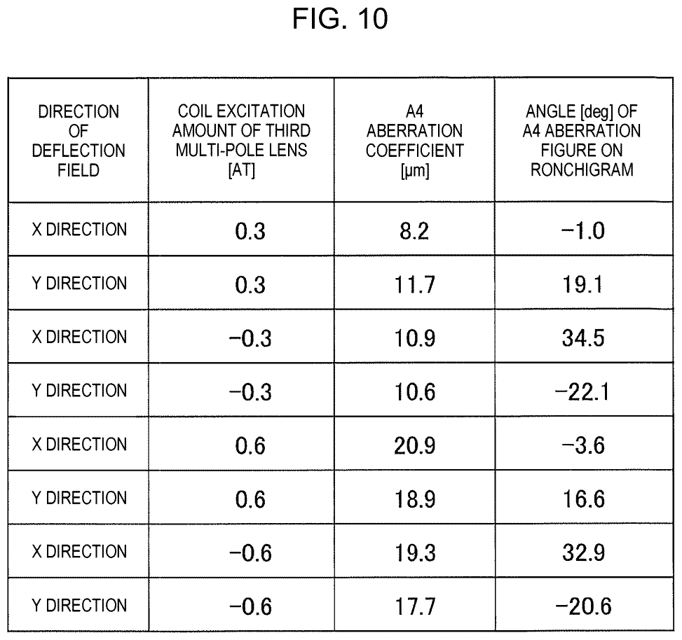

FIG. 10 is a table showing an average value of an A4 aberration coefficient and an average value of a rotation angle of the A4 aberration figure when the deflection fields of 0.3 AT in the four directions (X+ direction, X− direction, Y+ direction, and Y− direction) are introduced into the third multi-pole lens 205 and when the deflection fields of 0.6 AT in the four directions (X+ direction, X− direction, Y+ direction, and Y− direction) are introduced into the third multi-pole lens 205 in a certain experiment.

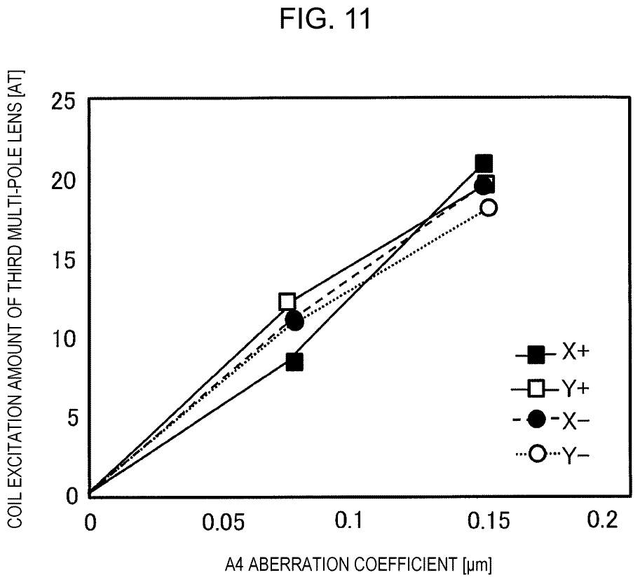

FIG. 11 is a graph showing a relationship between a coil excitation amount of the third multi-pole lens 205 and the A4 aberration coefficient generated accordingly in another experiment.

It can be seen from FIG. 11 that the A4 aberration is linearly introduced into the deflection field provided to the third multi-pole lens 205. This tendency also applies to any of the four directions (X+ direction, X-direction, Y+ direction, and Y-direction).

As described above, according to the aberration correction device and the aberration correction method in the present embodiment, it is possible to achieve both the corrections of the A1 aberration or the A4 aberration and improvement on image quality by reducing the beam deflection sensitivity of the multi-pole lens.

The invention is not limited to the embodiments described above, and includes various modifications. For example, the embodiment described above is described in detail to facilitate understanding of the invention, and the invention is not necessarily limited to those including all the described configurations. A part of a configuration in each embodiment may be added to, deleted from, or replaced with another configuration.

### REFERENCE SIGNS LIST

100: STEM apparatus (charged particle beam apparatus)
101: lens barrel
102: control unit
103: electron source
104: focusing lens group
105: aberration correction device
106: objective lens
107: sample stage
108: sample holder
109: image forming lens group
110: annular detector
111: transmission electron detector
112: imaging camera
201: first deflection coil
202: first adjustment lens
203: first multi-pole lens
204: first transfer lens
205: third multi-pole lens (first deflector)
206: second transfer lens
207: third transfer lens
208: second deflection coil (second deflector)
209: fourth transfer lens
210: second multi-pole lens
211: third deflection coil
212: second adjustment lens
213: beam trajectory
300: pole lens
301: magnetic path
302: main coil
303: sub coil
304: magnetic pole
401: power supply
501: power supply
601: center trajectory
701: center trajectory
805: shadow of aperture
806: target

1. An aberration correction device that corrects an aberration of an optical system, the aberration correction device comprising:
a first multi-pole lens configured to generate a first 6-pole field;
a second multi-pole lens configured to generate a second 6-pole field;
a first deflector configured to generate a first deflection field; and
a second deflector configured to generate a second deflection field, wherein
the first deflector is arranged at a position of a beam cross between the first multi-pole lens and the second multi-pole lens,
the second deflector is arranged between the first deflector and the first multi-pole lens or the second multi-pole lens, and
the aberration correction device
returns, by the second deflector, a beam deflected by the first deflector,
allows the beam to pass through at least one center of the first multi-pole lens or the second multi-pole lens, and
accordingly, corrects at least one of a 2-fold symmetric first-order astigmatism (A1) aberration or a 5-fold symmetric fourth-order astigmatism (A4) aberration.

2. The aberration correction device according to claim 1, wherein
the aberration correction device corrects the 2-fold symmetric first-order astigmatism (A1) aberration and the 5-fold symmetric fourth-order astigmatism (A4) aberration.

3. The aberration correction device according to claim 1, wherein
a number of positions of the beam cross between the first multi-pole lens and the second multi-pole lens is an even number.

4. The aberration correction device according to claim 1, wherein
the first deflector is a multi-pole lens.

5. The aberration correction device according to claim 1, wherein
the second deflector includes two deflection elements, and accordingly, the second deflector is configured to independently control a deflection and a translation of the beam.

6. An aberration correction method performed by a charged particle beam apparatus including an aberration correction device that corrects an aberration of an optical system, the aberration correction device including
a first multi-pole lens configured to generate a first 6-pole field,
a second multi-pole lens configured to generate a second 6-pole field,
a first deflector configured to generate a first deflection field, and
a second deflector configured to generate a second deflection field, in which
the first deflector is arranged at a position of a beam cross between the first multi-pole lens and the second multi-pole lens, and
the second deflector is arranged between the first deflector and the first multi-pole lens or the second multi-pole lens,
the aberration correction method comprising:
returning, by the second deflector, a beam deflected by the first deflector;
allowing the beam to pass through at least one center of the first multi-pole lens or the second multi-pole lens; and
accordingly, correcting at least one of a 2-fold symmetric first-order astigmatism (A1) aberration or a 5-fold symmetric fourth-order astigmatism (A4) aberration.

7. The aberration correction method according to claim 6, wherein
the aberration correction device corrects the 2-fold symmetric first-order astigmatism (A1) aberration and the 5-fold symmetric fourth-order astigmatism (A4) aberration.

8. The aberration correction method according to claim 6, wherein
a number of positions of the beam cross between the first multi-pole lens and the second multi-pole lens is an even number.

9. The aberration correction method according to claim 7, wherein
the aberration correction device corrects the 2-fold symmetric first-order astigmatism (A1) aberration generated by correcting the 5-fold symmetric fourth-order astigmatism (A4) aberration by
deflecting the beam by the second deflector, and
translating an optical axis with respect to the second 6-pole field.
